(19) United States
(12) Patent Application Publication
(10) Pub. No.: US 2015/0338879 A1
(43) Pub. Date: Nov. 26, 2015

(54) CIRCUIT BOARD DEVICE

(71) Applicant: Kabushiki Kaisha Toshiba, Tokyo (JP)

(72) Inventors: Syuji Hiramoto, Tokyo (JP); Hideki Ogawa, Hino Tokyo (JP)

(21) Appl. No.: 14/637,133

(22) Filed: Mar. 3, 2015

Related U.S. Application Data
(60) Provisional application No. 62/002,683, filed on May 23, 2014.

(51) Int. Cl. G06F 1/16; H05K 1/18; H05K 1/02

(52) U.S. Cl. CPC G06F 1/163; H05K 1/028; H05K 1/181; G06F 1/1652; H05K 2201/10083; H05K 2201/10037; H05K 2201/10128

(57) ABSTRACT

According to one embodiment, a circuit board device includes a flexible printed circuit board configured to be bendable and including a first mounting surface and a second mounting surface opposed to the first mounting surface, at least one electronic component mounted on the first mounting surface of the flexible printed circuit board, and a plurality of bent portions on both sides of the electronic component near the electronic component, the bent portions being formed by folding a part of the flexible printed circuit board.

### CROSS-REFERENCE TO RELATED APPLICATIONS

This application claims the benefit of U.S. Provisional Application No. 62/002,683, filed May 23, 2014, the entire contents of which are incorporated herein by reference.

### FIELD

Embodiments described herein relate generally to a circuit board device usable in a wearable electronic device.

### BACKGROUND

Recently, a market for wearable terminals (wearable electronic devices) has emerged. Such terminals include, for example, bracelet (wristband) terminals and glasses terminals. Wearable terminals are information terminals which are worn by the user at all times to record the physical condition or the movement of the body. In, for example, a terminal that encircles the arm, such as a wristband terminal, a printed circuit board which is easily bent, such as a flexible printed circuit (FPC) board, is useful.

However, FPC boards, being flexible and so lacking the rigidity of conventional circuit boards, increase the likelihood of stress being applied to the soldered portions of electronic components mounted on the FPC board, such as the soldered portions of ball grid arrays (BGAs) when the FPC board is bent in use. Because of this, with regard to components which are weak in distortion, a reinforcing plate is attached to the surface opposite to (or the back of) the component mounting surface of the FPC board. Alternatively, an adhesive agent or an under-filler material may be applied to the component mounting portion to add reinforcement.

However, attaching a reinforcing plate to the back of an FPC board makes the whole board thick and heavy. In addition, since an electronic component cannot be mounted where the reinforcing plate is attached, mounting space is wasted. The method of applying an adhesive agent or an under-filler material increases the cost by increasing the number of manufacturing processes.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective view showing a wristband wearable electronic device according to a first embodiment;

FIG. 2 is a perspective view showing a circuit board device housed in the electronic device;

FIG. 3 is an exploded perspective illustration showing a part of the circuit board device;

FIG. 4 is a cross-sectional view of the electronic device taken along line IV-IV of FIG. 1;

FIG. 5 is a block diagram schematically showing structures of electronic components of the electronic device;

FIG. 6 is a perspective view showing an electronic component mounting portion of a circuit board device according to a second embodiment;

FIG. 7A is a perspective view showing the electronic component mounting portion before a reinforcing bent portion of the circuit board device of the second embodiment is cut and raised;

FIG. 7B is a perspective view showing the electronic component mounting portion after the reinforcing bent portion of the circuit board device of the second embodiment is cut and raised;

FIG. 8A is an exploded perspective view showing an electronic component mounting portion of a circuit board device according to a third embodiment; and

FIG. 8B is a cross-sectional view of the circuit board device along line IXB-IXB of FIG. 8A.

### DETAILED DESCRIPTION

Various embodiments will be described hereinafter with reference to the accompanying drawings. In general, according to one embodiment, a circuit board device comprises: a flexible printed circuit board configured to be bendable and comprising a first mounting surface and a second mounting surface opposed to the first mounting surface; at least one electronic component mounted on the first mounting surface of the flexible printed circuit board; and a plurality of bent portions on both sides of the electronic component near the electronic component, the bent portions being formed by folding a part of the flexible printed circuit board.

### First Embodiment

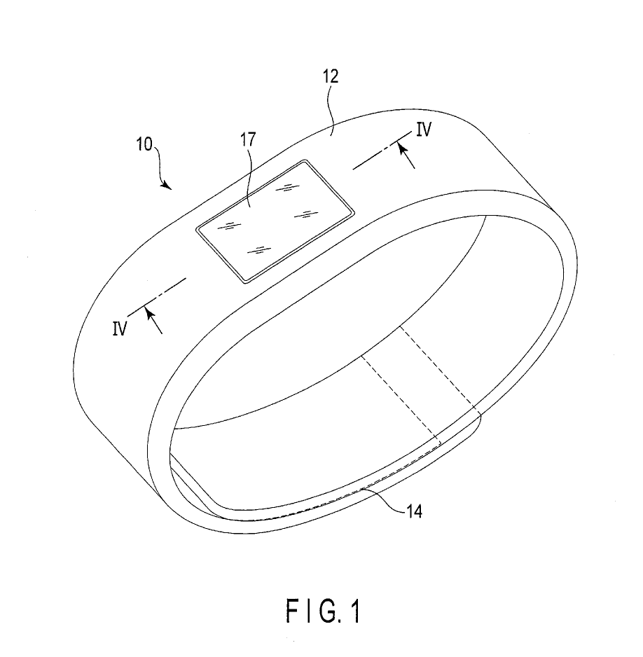

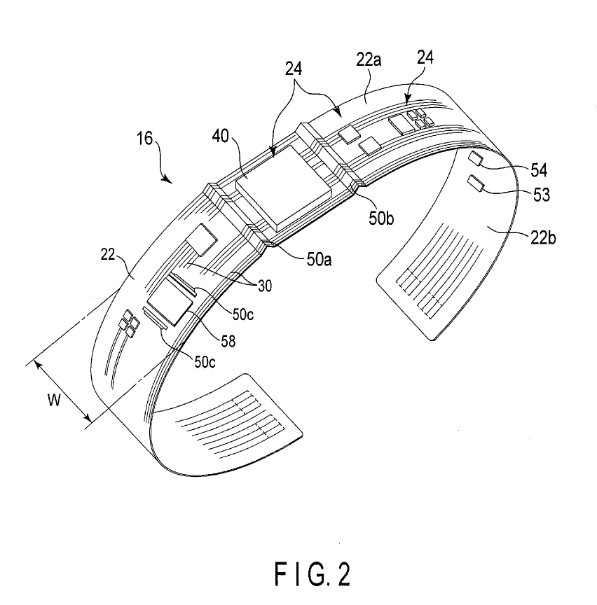

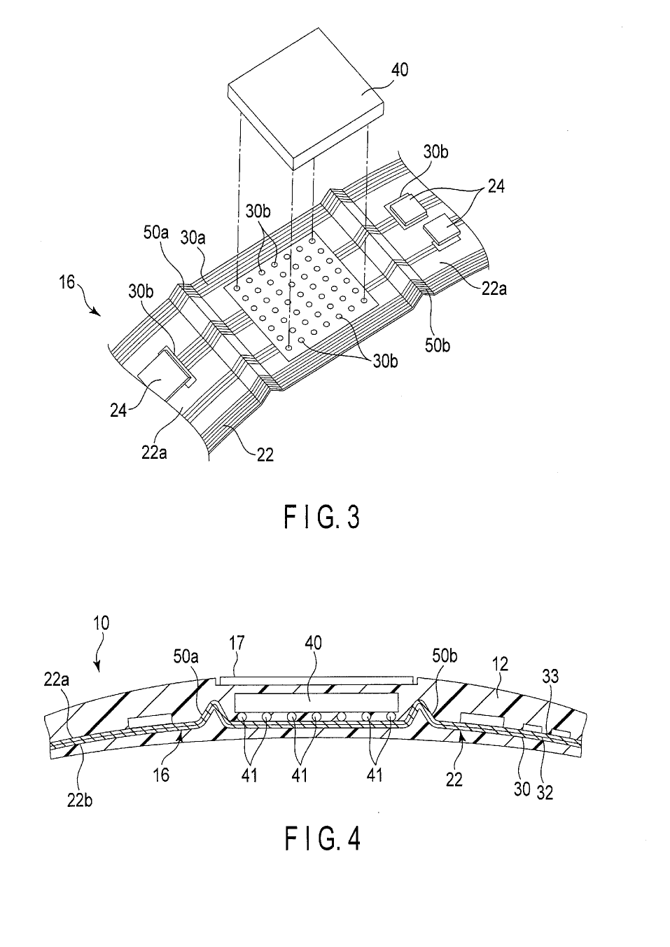

FIG. 1 is a perspective view showing a wristband wearable electronic device according to a first embodiment. FIG. 2 is a perspective view showing a circuit board device housed in the electronic device. FIG. 3 is an exploded perspective view showing a part of the circuit board device. FIG. 4 is a cross-sectional view of the electronic device taken along line IV-IV of FIG. 1.

As shown in FIG. 1, a wearable electronic device 10 comprises, for example, an envelope (outer case) or main body 12 which is formed into a long and thin band-shape from a synthetic resin. The main body 12 is flexible and freely bendable. For example, as fastener elements, hook-and-loop fasteners 14 are attached to both end portions of the main body 12 in the longitudinal direction. These end portions of the main body 12 are overlapped and attached to each other by the hook-and-loop fasteners 14. Thus, a loop wristband is structured and can be mounted on a wrist of a body. The fastener elements are not limited to hook-and-loop fasteners, and may be, for example, a combination of an engaging hole and an engaging protrusion, or a combination of an engaging hole and a hook. Thus, the fastener elements may be selected in various ways.

A rectangular display 17 is provided at the substantially central portion of the main body 12 in the longitudinal direction. The display 17 is provided on the surface of the main body 12. This surface is the outer circumferential surface when the main body 12 is bent.

As shown in FIG. 2 to FIG. 4, the electronic device 10 comprises, for example, an embedded circuit board device 16 housed in the main body 12. The circuit board device 16 comprises a flexible printed circuit (FPC) board 22 formed into a long and thin band, and a plurality of electronic components 24 mounted on the mounting surface of the FPC board 22. The FPC board 22 is formed into a band-shape which is substantially the same as the main body 12 in length and which is slightly narrower than the main body 12. The EPC board 22 extends over substantially the entire length of the main body 12.

As shown in FIG. 4, the FPC board 22 comprises, for example, a basal insulating layer 30, a conductive layer 32 which is formed on the insulating layer 30 and which constitutes a plurality of interconnects 30a and a plurality of connection pads 30b, and a protection layer (an insulating layer or a solder resist layer) 33 which is piled and formed on the conductive layer 32. A multilayered FPC board in which a plurality of insulating layers and a plurality of conductive layers are further stacked may be employed for the FPC board 22. As shown in FIG. 2, the FPC board 22 can be easily bent in the longitudinal direction, and comprises a first mounting surface 22a and a second mounting surface 22b. The first mounting surface 22a is the outer circumferential surface when the FPC board 22 is bent. The second mounting surface 22b is the inner circumferential surface on the side opposite to the first mounting surface 22a.

FIG. 5 schematically shows circuit structures of electronic components of the circuit board device 16. The circuit board device 16 comprises a CPU 40 which is a semiconductor device, two clock signal oscillators 41a and 41b connected to the CPU 40, a charger IC 42, a power source 44, the display 17, an antenna 50 connected to the CPU 40 via a band pass filter 48, a microphone 52 as a first sensor, a pressure sensor 53 as a second sensor, a thermal sensor 54 as a third sensor, an LED 56 as a lighting module, a GPS module 58, a near field communication module 60 and an operation button 61, etc. The CPU 40 is formed in, for example, a ball grid array (BGA) package. The CPU 40 may include an acceleration sensor, an angular velocity sensor and a geomagnetic sensor, etc. The CPU 40 has a communication function, a processor function for processing data input from each sensor and a memory function for storing data. The CPU 40 is able to display various types of data in the display 17 and transfer processed data to an external portable terminal such as a smartphone and a tablet PC. At the same time, the CPU 40 has a function for loading various types of data from an external terminal.

As shown in FIG. 2 to FIG. 4, among the plurality of electronic components 24, various types of sensors such as the microphone 52, the pressure sensor 53 and the thermal sensor 54 are mounted on the second mounting surface 22b of the FPC board 22 in such a way that the sensors can be close to a body. Except for the display 17, the other electronic components 24 (the CPU 40, the clock oscillators 41a and 41b, the charger IC, the power source 44, the band pass filter 48 and the GPS module 58, etc.,) are mounted on the first mounting surface 22a of the FPC board 22.

The CPU 40 is mounted on, for example, the first mounting surface 22a in the central portion of the FPC board 22 in the longitudinal direction. The CPU 40 structured in the BGA package has, for example, a 3 mm-square rectangular shape. A plurality of solder balls 41 are bonded to (soldered with) the plurality of connection pads 30b provided in the placement area of the FPC board 22, thereby mounting the CPU 40 on the first mounting surface 22a of the FPC board 22. Thus, the CPU 40 is electrically connected to the plurality of interconnects 30a of the FPC board 22. For example, the CPU 40 is provided in such a way that two sides facing each other are parallel to the side edges of the FPC board 22. The other electronic components 24 are appropriately dispersed and mounted on the first mounting surface 22a of the FPC board 22.

As shown in FIG. 2 to FIG. 4, the FPC board 22 comprises a plurality of bent portions which function as reinforcing portions. The bent portions are provided near, from the electronic components 24, a component which has a comparatively large dimension such as an electronic component which has a dimension of 50 to 100% of width W of the FPC board 22. In this embodiment, the FPC board 22 comprises a first bent portion 50a and a second bent portion 50b which are provided near both sides of the CPU 40 in the longitudinal direction of the FPC board 22. Each of the first and second bent portions 50a and 50b is formed by valley-folding, mountain-folding and valley-folding the FPC board 22. In this manner, each of the first and second bent portions 50a and 50b is made convex on the first mounting surface 22a side and has a triangle cross-section. The first and second bent portions 50a and 50b extend over the whole width of the FPC board 22. Further, the first and second bent portions 50a and 50b extend in a direction orthogonal to the side edges of the FPC board 22, or in other words, extend in the width direction of the FPC board 22. Thus, the CPU 40 is positioned between the first and second bent portions 50a and 50b in the longitudinal direction of the FPC board 22. The protrusion height of each of bent portions 50a and 50b (height from the first mounting surface 22a) is preferably less than or equal to the height (thickness) of the mounted CPU 40.

As shown in FIG. 2, a plurality of bent portions 50c may be provided near an electronic component such as the GPS module 58.

As described above, the first and second bent portions 50a and 50b are provided near both sides of the CPU 40, thereby reinforcing the mounting area in which the CPU 40 is mounted and improving the rigidity. Even in the case where the FPC board 22 is bent into a loop-shape, the mounting area can be maintained in a substantially flat state, and it is possible to considerably reduce the stress or load applied to the joint portion (soldering portion) of the CPU 40.

As shown in FIG. 1 and FIG. 4, the circuit board device 16 structured as described above is covered by the main body 12. The main body 12 is integrally formed by filling a synthetic resin into the surrounding area of the circuit board device 16. The main body 12 is not limited to this structure. For example, the main body 12 may be formed of two dividable resin covers in such a way that the circuit board device 16 is covered by the resin covers from both surfaces.

According to the circuit board device 16 and the electronic device 10 in the first embodiment described above, the whole board is structured by the FPC board without using a rigid printed circuit board. This structure realizes reduction in weight and size of the circuit board device 16 and the electronic device 10, and improvement in flexibility. The bent portions of the FPC board are provided near the mounting area of an electronic component in order to reinforce the mounting area of the FPC board and improve the rigidity. Thus, there is no need to add a reinforcing member such as a reinforcing plate to the FPC board. The whole area of the FPC board can be used as a mounting area. This means that an electronic component can be also mounted on the back surface side of the CPU. In the FPC board 22, a high reinforcing effect can be realized by an easy folding process without impairing characteristics such as thinness, lightness and mounting in high density.

Next, a circuit board device according to another embodiment is explained. In the embodiment explained below, portions identical to the above first embodiment will be denoted by the same reference numbers, and detailed explanations of such portions will be omitted. Hereinafter, structures or portions different from the first embodiment will be mainly explained in detailed.

### Second Embodiment

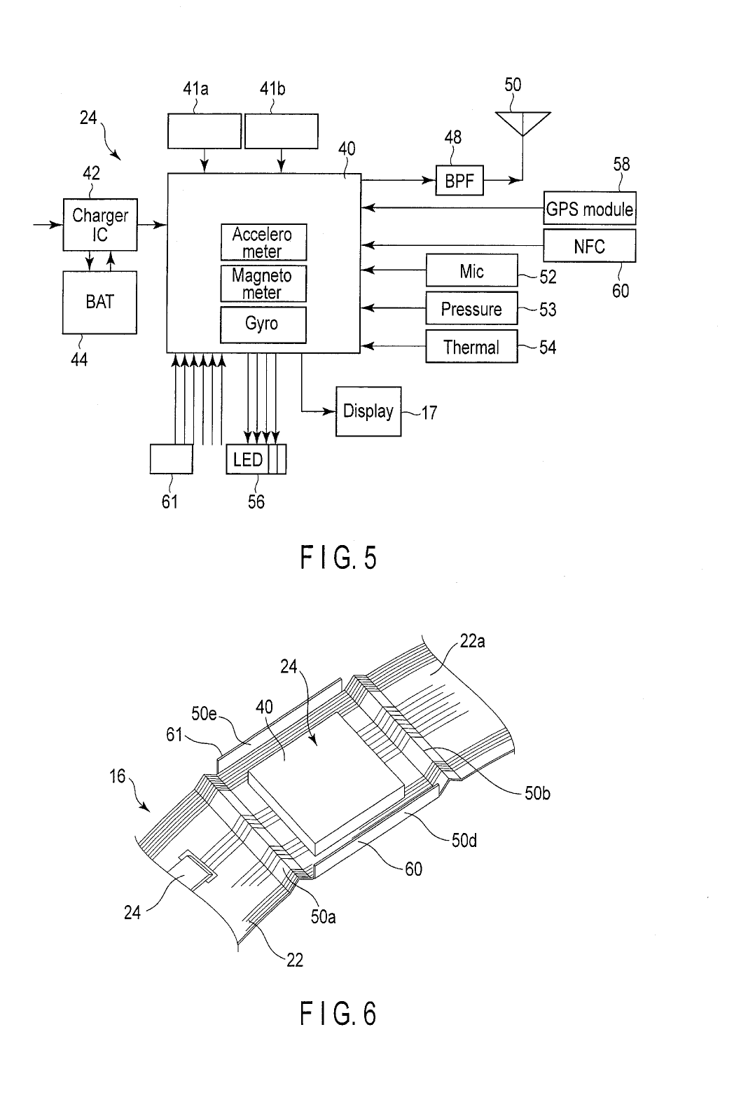

FIG. 6 is a perspective view showing a part of a circuit board device according to a second embodiment.

According to this embodiment, an FPC board 22 of the circuit board device 16 integrally comprises two protrusions 60 and 61 each of which protrudes from a corresponding side edge. The protrusions 60 and 61 are folded at a right angle on the first mounting surface 22a side along the side edges of the FPC board 22, and form bent portions 50d and 50e respectively. The bent portions 50d and 50e are provided on both sides of the mounting area in which a CPU 40 is mounted in the width direction. The bent portions 50d and 50e extend in the longitudinal direction of the FPC board 22 along the side edges of the FPC board 22. Further, bent portions 50d and 50e are longer than the length of the CPU 40 in the longitudinal direction of the FPC board 22 and face the whole mounting area of the CPU 40. The height of each of the bent portions 50d and 50e is preferably less than or equal to the height of the CPU 40.

The FPC board 22 may comprise first and second bent portions 50a and 50b. The first and second bent portions 50a and 50b extend in the width direction of the FPC board 22, and are adjacent to both sides of the mounting area of the CPU 40 in the longitudinal direction of the FPC board 22.

According to the second embodiment structured as described above, the bent portions 50d and 50e enable reinforcement of the mounting area of the CPU 40 and improvement in rigidity. Further, the bent portions 50d and 50e can be formed by an easier process of merely folding protrusions at a right angle.

The bent portions 50d and 50e may be shorter than the mounting area of the CPU 40 in length, or may be divided into a plurality of portions in the longitudinal direction. The bent portions are not limited to the structure in which they are provided on both sides of the CPU 40. One bent portion may be provided on one side only. The direction in which the bent portions extend is not limited to the longitudinal direction or width direction of the FPC board 22, and may be an arbitrary direction.

### Third Embodiment

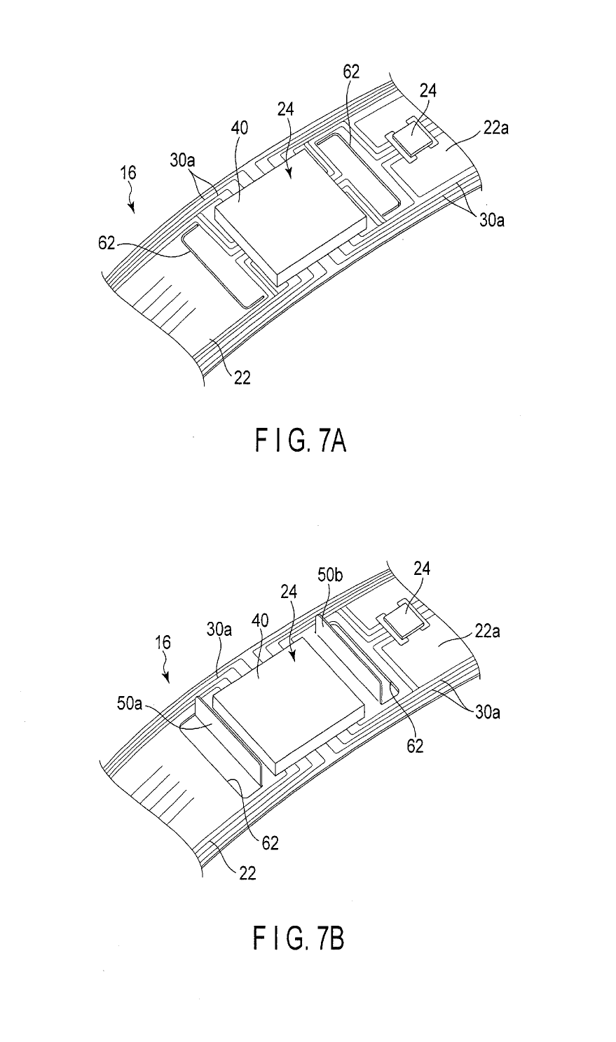

FIG. 7A and FIG. 7B are perspective views showing an electronic component mounting portion of a circuit board device according to a third embodiment. In this embodiment, slits 62 are formed in an FPC board 22. A first bent portion 50a and a second bent portion 50b are formed by cutting and raising a part of the FPC board 22, or in other words, by folding the portions cut by the slits 62 at a right angle toward the first mounting surface 22a side. The first and second bent portions 50a and 50b extend in the width direction of the FPC board 22, and are adjacent to both sides of the mounting area of a CPU 40 in the longitudinal direction of the FPC board 22. The height of each of the first and second bent portions 50a and 50b is preferably less than or equal to the height of the CPU 40.

The first and second bent portions 50a and 50b explained above enable reinforcement of the mounting area of the CPU 40 which is an electronic component and improvement in rigidity.

### Fourth Embodiment

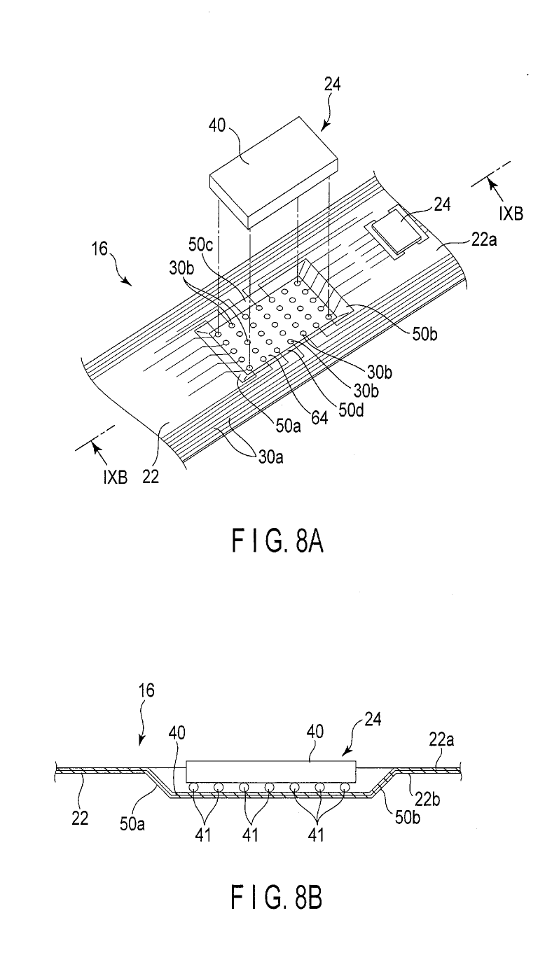

FIG. 8A is a perspective view showing an electronic component mounting portion of a circuit board device according to a fourth embodiment. FIG. 8B is a cross-sectional view of the circuit board device taken along line IXB-IXB of FIG. 8A. According to this embodiment, a rectangular recessed portion 64 is formed by applying a press process to the mounting area of a CPU 40 in an FPC board 22. The four sides of the recessed portion 64 are valley-folded and mountain-folded in order to form first to fourth bent portions 50a, 50b, 50c and 50d. In sum, the four bent portions 50a, 50b, 50c and 50d extend in the longitudinal direction and width direction of the FPC board 22 in order to surround the mounting area.

A plurality of connection pads 30b are provided on the bottom surface of the recessed portion 64. The CPU 40 is mounted on the bottom surface of the recessed portion 64 and is joined to the connection pads 30b. The height of each of the first to fourth bent portions 50a, 50b, 50c and 50d is preferably less than or equal to the height of the CPU 40.

The first to fourth bent portions 50a, 50b, 50c and 50d of the FPC board 22 described above enable reinforcement of the mounting area of an electronic component in the FPC board 22 and improvement in rigidity.

According to the first to fourth embodiments structured as described above, by structuring the whole board by the FPC board without using a rigid printed circuit board, it is possible to obtain the circuit board device and the wearable electronic device in which the weight and size can be easily reduced. In addition, without use of an additional member such as a reinforcing plate, it is possible to improve the rigidity of the component mounting area of the FPC board, prevent electronic components from being damaged or detached, and improve reliability. A high reinforcing effect can be realized by an easy folding process without impairing characteristics of the flexible printed circuit board such as thinness, lightness and mounting in high density.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, electronic components to be mounted in the mounting area reinforced by bent portions of the FPC board are not limited to a semiconductor device having a BGA structure, etc., and may be various electronic components such as a connector and an LED. The circuit board device may be applied to various electronic devices or various wearable electronic devices as well as a wristband wearable terminal.

What is claimed is:

1. A circuit board device used for a wearable electronic device, comprising:
a printed circuit board configured to be bendable comprising:
a first mounting surface;
a second mounting surface opposite of the first mounting surface;
at least one electronic component mounted on the first mounting surface of the printed circuit board; and
bent portions on both sides of the electronic component near the electronic component, the bent portions being a folded part of the printed circuit board and comprising a protrusion height.

2. The circuit board device of claim 1, wherein each of the bent portions comprises a convex cross-sectional shape comprising a valley folded part and a mountain folded part.

3. The circuit board device of claim 2, wherein the flexible printed circuit board further comprises side edges extending substantially parallel to each other, and the bent portions extend in a direction intersecting the side edges and are positioned on the both sides of the electronic component.

4. The circuit board device of claim 1, wherein the flexible printed circuit board further comprises side edges extending substantially parallel to each other; and
a protrusion protruding from each of the side edges, and each of the bent portions comprises a folded protrusion folded toward the first mounting surface side along the side edges.

5. The circuit board device of claim 4, wherein the bent portions further include a second bent portion comprising a folded portion of the printed circuit board, the second bent portion comprising a convex cross-sectional shape, extending in a direction intersecting the side edges and being positioned on each of the both sides of the electronic component.

6. The circuit board device of claim 1, wherein the flexible printed circuit board further comprises a slit having a substantially U-shape, and each of the bent portions comprising a folded area surrounded by the slit of the printed circuit board toward the first mounting surface side.

7. The circuit board device of claim 6, wherein the flexible printed circuit board further comprises side edges extending substantially parallel to each other, and the bent portions extend in a direction intersecting the side edges and are positioned on the both sides of the electronic component.

8. The circuit board device of claim 1, wherein the bent portions protrude from the first mounting surface, and a protrusion height of each of the bent portions is less than or equal to a height of the electronic component.

9. The circuit board device of claim 1, wherein the first mounting surface of the flexible printed circuit board comprises a convex shape.

10. A circuit board device comprising:
a flexible printed circuit board configured to be bendable comprising:
a first mounting surface;
a second mounting surface opposite of the first mounting surface;
at least one electronic component mounted on the first mounting surface of the flexible printed circuit board; and
a bent portion on a side of the electronic component near the electronic component, the bent portion comprising a folded part of the printed circuit board.

11. A wearable electronic device comprising:
a circuit board device comprising: a flexible printed circuit board configured to be bendable comprising:
a first mounting surface;
a second mounting surface opposite of the first mounting surface;
at least one electronic component mounted on the first mounting surface of the flexible printed circuit board; and
bent portions on both sides of the electronic component near the electronic component, each of the bent portions comprising a folded part of the printed circuit board; and
a flexible main body configured to be bendable and to cover an area around the circuit board device.
